(19) United States
(12) Patent Application Publication
(10) Pub. No.: US 2005/0095906 A1
(43) Pub. Date: May 5, 2005

(54) Socket connector with reliable retaining means

(75) Inventors: Wen He, Kunsan (CN); Fujin Peng, Kunsan (CN); Nick Lin, Tu-Chen (TW)

Correspondence Address: WEI TE CHUNG;FOXCONN INTERNATIONAL, INC., 1650 MEMOREX DRIVE, SANTA CLARA, CA, 95050, US

(73) Assignee: HON HAI PRECISION IND. CO., LTD.

(21) Appl. No.: 10/979,704

(22) Filed: Nov. 1, 2004

(30) Foreign Application Priority Data
Oct. 31, 2003 (TW) 92219415

(51) Int. Cl. H05K 1/00

(52) U.S. Cl. 439/526

(57) ABSTRACT

A socket connector (9) includes an insulative base (10), a plurality of contacts (20) and a flexible beam (120) for securing the electronic element in the base. The base includes sidewalls (12), and a recessed portion (13) being defined in the sidewalls for receiving the electronic element therein. A plurality of receiving passageways (110) are defined in the recessed portion and extend through upper and lower surfaces of the recessed portion. Each contact includes a retaining portion retained in the base, a flexible contact portion (200) extending laterally from an upper portion of the retaining portion beyond upper surface of the recessed portion, and a connecting porting (202) extending from a lower portion of the retaining portion adapted for electrically connecting with the PCB. The beam is secured with one sidewall of the base. The sidewall defines a slot (121) adjacent to the beam. The beam has a flexible portion (120A) extending into the recessed portion and deflectable into said slot in an opposite direction to the extending direction of the contact portions of the contacts.

### 1. FIELD OF THE INVENTION

The present invention relates to a socket connector mounted on a Printed Circuit Board (PCB) for receiving an IC chip or the like therein.

### 2. DESCRIPTION OF RELATED ART

Socket connectors are commonly used for connecting IC chips to a PCB. Normally, the socket connector has an insulative base and a plurality of conductive contacts. The insulative base defines a recessed portion configured to receive the IC chip therein. A plurality of passageways is defined through the recessed portion in an upper-to-lower direction. Each contact is received in a corresponding passageway with a contact portion extending beyond an upper surface of the base for electrically engaging with the IC chip and a connecting portion extending downwardly for connecting with the PCB. Some socket connectors are provided with retaining means besides the recessed portion for securely retaining the IC chip therein.

FIGS. 1-3 discloses a prior socket connector design of the common assignee. The socket connector includes an insulative base 6 defining a plurality of receiving passageways 60 and a plurality of contacts 5 respectively received in the receiving passageways 60. The insulative base 6 includes two pairs of sidewalls 61 and a recessed portion 65 in the sidewalls 61 for receiving the IC chip 7 therein. A cantilevered beam 611 is integrally formed on and extending along one sidewall 6. Each contact is generally C-shaped and oriented to the beam 611 and substantially orthogonal to the beam 611. A contact portion 50 is formed on an upper distal end of each contact 5 for connecting with the IC chip 7. A free end of the beam 611 extends into the recessed portion 65. A slot 610 is formed in the sidewall 61 adjacent to the beam 611, whereby the beam 611 is deflectable into the slot 610 upon insertion of the IC chip 7.

When the IC chip 7 is received in the recessed portion 65, and the IC chip 7 exerts a pressure to the contact portions 50 of the contacts 5. The contact portions 50 of the 5 moves in a slant downward direction S′ which can be divided into a lateral movement S1′ and a downward movement S2′. And thus a frictional force F′ oriented toward to the beam 611 is exerted on the IC chip 7 by the contacts 5, which is a disadvantage to securely retain the IC chip 7 in the recessed portion 65.

Hence, an improved socket connector is desired to overcome the disadvantages of the prior art.

### SUMMARY OF THE INVENTION

Accordingly, an object of the present invention is to provide a socket connector with reliably retaining means for an IC chip.

In order to achieve the object set forth, a socket connector is mounted on a Printed Circuit Board (PCB) and adapted for receiving an electronic element therein. The socket connector includes an insulative base, a plurality of contacts received in the base and a flexible beam for securing the electronic element in the base. The base includes sidewalls, and a recessed portion being defined in the sidewalls for receiving the electronic element therein. A plurality of receiving passageways is defined in the recessed portion and extends through upper and lower surfaces of the recessed portion. Each contact includes a retaining portion retained in the base, a flexible contact portion extending laterally from an upper portion of the retaining portion beyond upper surface of the recessed portion, and a connecting porting extending from a lower portion of the retaining portion adapted for electrically connecting with the PCB. The beam is secured with one sidewall of the base. The sidewall defines a slot adjacent to the beam. The beam has a flexible portion extending into the recessed portion and deflectable into said slot in an opposite direction to the extending direction of the contact portions of the contacts.

Other objects, advantages and novel features of the invention will become more apparent from the following detailed description of the present embodiment when take in conjunction with the accompany drawings.

### BRIEF DESCRIPTION OF THE DRAWINGS

FIG. 1 is a perspective view of a conventional socket connector mounted on a Printed Circuit Board together with an IC chip to be received in the socket connector;

FIG. 2 is an assembled view of FIG. 1;

FIG. 3 is a sectional view of the conventional socket connector along line 3-3 of FIG. 2;

FIG. 4 is a perspective view of a socket connector in accordance with the present invention mounted on a Printed Circuit Board, together with an IC chip to be received in the socket connector;

FIG. 5 is an assembled view of FIG. 1;

FIG. 6 is a sectional view of the socket connector assembly along 6-6 of FIG. 2; and

FIG. 7 shows a perspective view of socket connector of a second embodiment of the invention, together with an IC chip to be received in the socket connector.

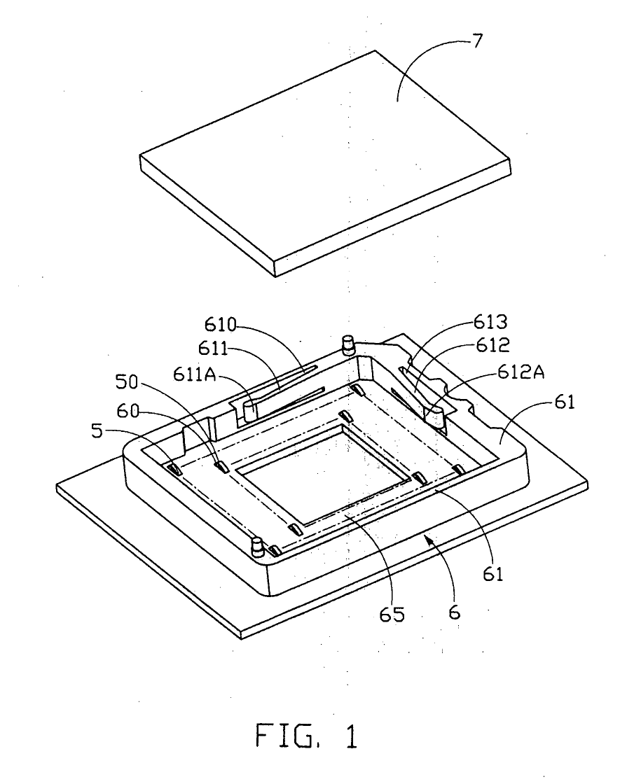

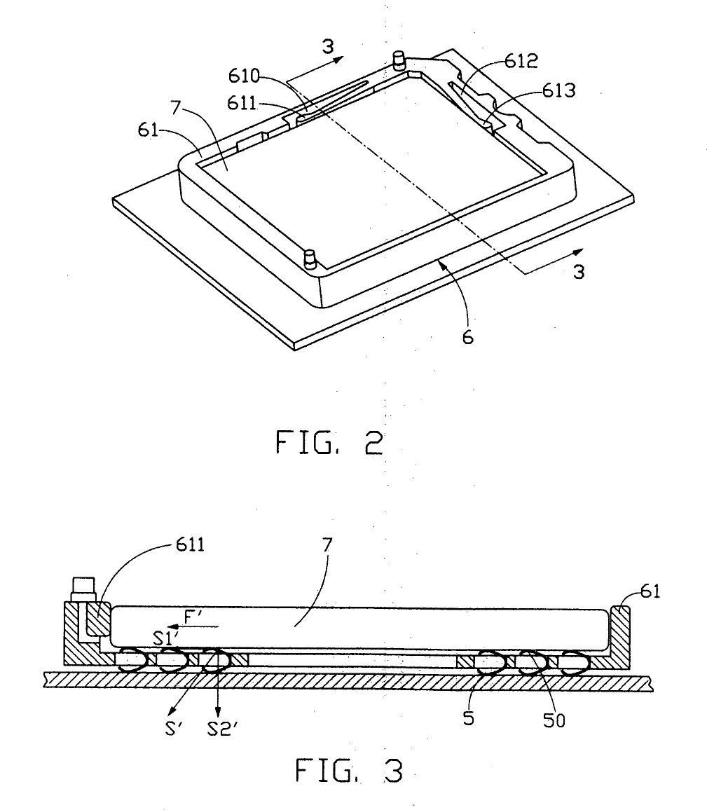

### DETAILED DESCRIPTION OF PREFERRED EMBODIMENTS

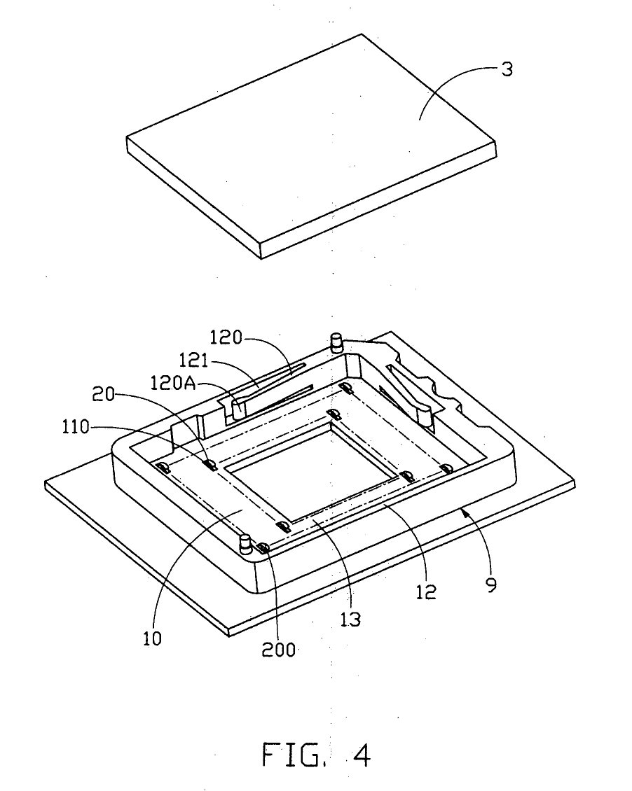

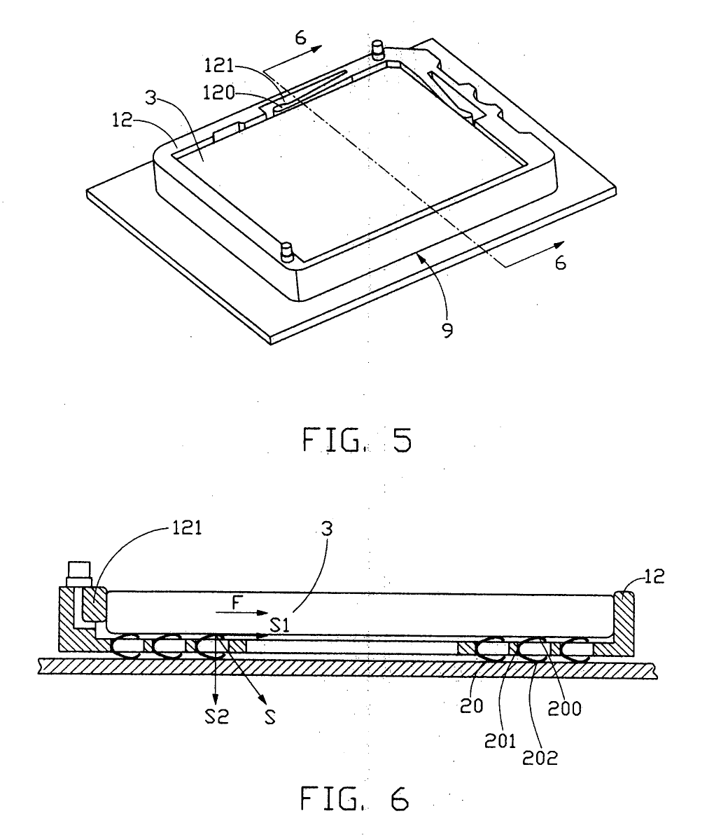

Referring to FIGS. 4, 5 and 6, a socket connector 9 in accordance with the present invention is mounted on a Printed Circuit Board (PCB, not labeled) for receiving an IC chip 3 therein. The socket connector 9 includes an insulative base 10 and a plurality of contacts 20 received in the base 10.

The insulative base 10, which is generally flat and rectangular shaped, includes two pairs of opposed sidewalls 12 and a recessed portion 13 in the sidewalls 12 for receiving the IC chip 3. The recessed portion 13 defines a plurality of receiving passageways 110 in matrix relationship through upper and lower surfaces thereof. A cantilevered beam 122 is integrally molded with one sidewall 12 of the base 10. The beam 122 extends from one end portion of said sidewall 12 and extends slantways along said sidewall 12 with a free flexible portion 120A extending into the recessed portion 13. A slot 121 is formed in said sidewall 12 adjacent to the beam 122, whereby the beam 122 is removable between the slot 121 and the recessed portion 13. In this embodiment, a similar beam 12 is formed with an adjacent sidewall 12.

Specially referring to FIG. 6, each contact 20 is substantially “C” shaped and includes a retaining portion 201 retained in a corresponding receiving passageway 110, a flexible contact portion 200 extending from an upper portion of the retaining portion 201, and a flexible connecting portion 202 extending from a lower portion of the retaining portion 201 generally along the same direction with the contact portion 200. The contact portion 200 and the connecting portion 202 respectively extending beyond top and bottom surfaces of the recessed portion 13 for respectively engaging with contact pads on the IC chip 3 and the PCB.

During assembly, the contacts 20 are mounted to the housing 10 with each retaining portions 201 retained in a corresponding receiving passageways 110. The contact portions 200 and the connecting portions 202 extend away from the flexible beam 120 of the base 10 and generally orthogonal to the flexible beam 120.

When an IC chip 3 is retained in the recessed portion 13, and the IC chip 3 exerts a pressure to the contact portions 200 of the contacts 20. The flexible beam 120 exerts a retained force F, substantially along the extending direction of the contact portion 200 (or connecting portions 202) of the contacts 20, to the IC chip 3. The retaining force F is passed to the contact portions 200 and the connecting portions 202. The contact portions 200 move in a slant downward direction S which can be divided into a lateral movement S1 and a downward movement S2. And thus a frictional force F oriented away from the beam 121 is exerted on the IC chip 3 by the contacts 20, whereby the beam 121 is protected from being destroyed and the IC chip 3 is retained securely in the recessed portion 13.

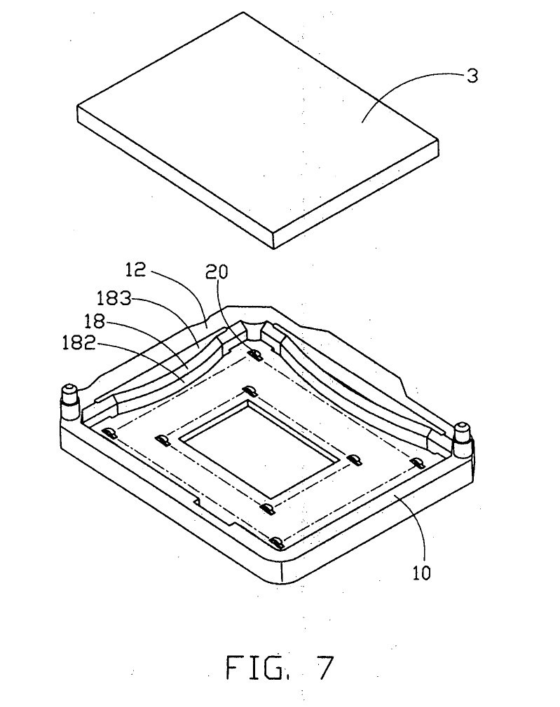

FIG. 7 shows a second embodiment of the present invention, wherein the beam 18 is an arced portion with opposite ends (not labeled) integrally molded with one sidewall 12 of the insulative housing 10. The beam 18 has a middle portion 182 between opposite ends and extending into the recessed portion of the base 10 for securing the IC chip 3 in the housing 10. A slot 183 is defined in the sidewall 12 adjacent to the middle portion 182 of the beam 18, whereby the middle portion 182 is deflectable from the recessed portion to the slot 183.

In the previously described embodiments, the contacts 20 are compression type with solderless connecting portions 202. Of course the connecting portions 202 can be flat type soldered to the PCB.

It is to be understood, however, that even though numerous characteristics and advantages of the present invention have been set forth in the foregoing description, together with details of the structure and function of the invention, the disclosure is illustrative only, and changes may be made in detail, especially in matters of shape, size, and arrangement of parts within the principles of the invention to the full extent indicated by the broad general meaning of the terms in which the appended claims are expressed.

1. A socket connector being mounted on a Printed Circuit Board and adapted for receiving an electronic element therein, comprising:
an insulative base including sidewalls and a recessed portion being defined in the sidewalls for receiving the electronic element therein, a plurality of receiving passageways being defined in the recessed portion and extending through upper and lower surfaces of the recessed portion;
a plurality of contacts received in the receiving passageways, each contact including a retaining portion retained in the base, a flexible contact portion extending laterally from an upper portion of the retaining portion beyond upper surface of the recessed portion, and a connecting porting extending from a lower portion of the retaining portion adapted for electrically connecting with the PCB; and
a beam being secured with one sidewall of the base, the sidewall defining a slot adjacent to the beam, the beam having a flexible portion extending into the recessed portion and deflectable into said slot in an opposite direction to the extending direction of the contact portions of the contacts.

2. The socket connector as described in claim 1, wherein the beam is integrally molded with the sidewall of the base.

3. The socket connector as described in claim 2, wherein the beam is a cantilevered beam with one end integrally molded with the sidewall of the base, said flexible portion is a free end portion extending from said one end.

4. The socket connector as described in claim 2, wherein the beam is substantially arced with opposite ends integrally molded with the sidewall of the base, said flexible portion is a middle curved portion between opposite ends.

5. The socket connector as described in claim 1, wherein each contact has a generally C shaped portion, the connecting portions of the contacts extending generally along the same direction with the contact portions.

6. The socket connector as described in claim 5, wherein the connecting portion of each contact is a flexible portion extending beyond the lower surface of the recessed portion.

7. A socket connector being mounted on a Printed Circuit Board (PCB) and adapted for receiving an IC chip therein, the socket connector comprising:
an insulative base defining a recessed portion adapted for receiving the IC chip therein, at least a pair of sidewalls being formed on opposite sides of the recessed portion, a plurality of receiving passageways though upper and lower surfaces of the recessed portion in a matrix arrangement;
a flexible beam extending substantially along one sidewall, the flexible beam has one end secured with said one sidewall and a flexible portion extending laterally into the recessed portion; and
a plurality of contacts received in the receiving passageways of the base, each contact having a retaining portion secured with the housing, a contact portion extending from the retaining portion toward the other of said pair of sidewall, and a connecting portion extending from the retaining portion adapted for engaging with the PCB.

8. The socket connector as described in claim 7, wherein the beam is a cantilevered beam with one end integrally molded with the sidewall of the base, said flexible portion is a free end portion extending from said one end.

9. The socket connector as described in claim 7, wherein the beam is substantially arced with opposite ends integrally molded with the sidewall of the base, said flexible portion is a middle curved portion between opposite ends.

10. A socket assembly comprising:
an insulative base defining an upward recess surrounded by side walls;
at least one resilient beam located about one of said side walls;
a plurality of contacts disposed in the base with upper contact portions extending upwardly into the recess;
an electronic device received in the recess and downwardly pressing against the upper contact portions to push the upper contact portion downwardly to the base, and laterally pressing against the at least one resilient beam to push the at least one resilient beam laterally to said one of the side wall; wherein
a displacement of said upper contact portion derived from downward installation of the electronic device into the recess, is a composition of downward and lateral movements, and a lateral component of said displacement is compliant with a lateral reaction force of said at least one resilient beam against said electronic device so as to assure that the at least one resilient beam will not experience undue lateral forces during installation.

11. The socket assembly as claimed in claim 10, wherein said lateral component is aligned with said lateral reaction force.
